(19) United States
(12) Patent Application Publication
(10) Pub. No.: US 2026/0348014 A1
(43) Pub. Date: Nov. 5, 2026

(54) SPATIAL ATOMIC LAYER DEPOSITION APPARATUS, HEAD, AND INSERT FOR HEAD

(71) Applicant: Nfinite Nanotechnology Inc., Waterloo (CA)

(72) Inventors: Chee Hau Teoh, Kitchener (CA); Jhi Yong Loke, Waterloo (CA); Trupal Jasmatbhai Goti, Kitchener (CA); Christopher David Howey, Toronto (CA)

(73) Assignee: Nfinite Nanotechnology Inc., Waterloo, ON (CA)

(21) Appl. No.: 19/486,358

(22) PCT Filed: May 23, 2024
(86) PCT No.: PCT/IB2024/055041

§ 371 Date: Nov. 20, 2025

Related U.S. Application Data
(60) Provisional application No. 63/468,399, filed on May 23, 2023.

(51) Int. Cl. C23C 16/455; C23C 16/54

(52) U.S. Cl. CPC C23C 16/45563; C23C 16/45544; C23C 16/545

(57) ABSTRACT

The present invention relates to an atomic layer deposition (SALD) head and an apparatus incorporating multiple SALD heads for providing gas to a flexible substrate. The SALD head includes a permeable material disposed between the input and output faces to ensure even gas distribution across the head's width. The permeable material can be a particulate, lattice structure, mesh, or porous media, with options including stainless steel balls, glass beads, fiberglass, and more. The permeable material may also exhibit a density gradient and be contained in a removable insert with segmented materials that control gas flow. This design enhances deposition uniformity and process control in atomic layer deposition applications on flexible substrates.

### CROSS-REFERENCE TO RELATED APPLICATION

This application claims the benefit of U.S. Provisional Patent Application No. 63/468,399 entitled “Compact SALD Head Arrangements and Configurable SALD Heads with Even Gas Flow”, filed May 23, 2023, the entire contents of which are incorporated herein by reference.

### FIELD

The present specification is directed to apparatuses for spatial atomic layer deposition (SALD), and specifically a SALD head for improved gas distribution.

### BACKGROUND

Spatial Atomic Layer Deposition (SALD) apparatuses, designed for thin-film deposition, apply materials in atomic layers onto a substrate. The technique involves sequential exposure to different precursor gases in a spatial arrangement, unlike the temporal exposure in traditional Atomic Layer Deposition (ALD). This method enhances deposition rates and enables continuous processing over large areas. However, ensuring even gas distribution across the substrate is challenging. Uneven distribution can lead to non-uniform film thickness, inconsistent chemical composition, defects, and reduced scalability, impacting the quality and reliability of the coatings in applications such as solar cells, displays, microelectronics, and food packaging.

### SUMMARY

An aspect of the specification provides an atomic layer deposition (SALD) head configured to provide a gas to a flexible substrate. The SALD head includes an input face configured to receive a gas, an output face configured to convey the gas onto the flexible substrate, and a permeable material disposed between the input face and the output face and configured to convey the gas from the input face to the output face, the permeable material configured to evenly distribute the gas with respect to a width of the SALD head.

In some examples, the permeable material includes one or more of: a particulate, a lattice structure, a mesh, and a porous media.

In some examples, the permeable material includes one or more of the following particulates: stainless steel balls, glass beads, glass microspheres, fiberglass, cellulose, grains, sand, powders, granules, dust, crushed rock, crystals, metal shavings, and pellets.

In some examples, the permeable material includes one or more of the following porous media: ceramic, polymer, metal, stainless steel wool, and filtration media.

In some examples, the permeable material includes a density gradient.

In some examples, the permeable material is housed in a removable insert.

In some examples, the removable insert includes a plurality of segments, and each segment includes a material to block flow of gas, a material to freely allow flow of gas, or the permeable material.

In some examples, the SALD head includes a plurality of gas channels, each gas channel configured to provide a gas to a respective one of the plurality of segments.

In some examples, the SALD head includes a plurality of chambers for receiving a plurality of respective inserts, including the removable insert.

In some examples, the SALD head includes a gas output slit disposed in the output face. The gas output slit has a non-rectangular shape to promote even flow of gas with respect to a width of the SALD head.

A further aspect of the specification provides an insert for a SALD head. The insert is configured to be inserted between an input face of the SALD head and an output face of the SALD head. The insert includes a permeable material configured to slow the flow of gas from the input face to the output face and evenly distribute a gas with respect to a width of the SALD head.

In some examples, the permeable material includes one or more of: a particulate, a lattice, a mesh, and a porous media.

In some examples, the permeable material includes one or more of the following particulates: stainless steel balls, glass beads, glass microspheres, fiberglass, cellulose, grains, sand, powders, granules, dust, crushed rock, crystals, metal shavings, and pellets.

In some examples, the permeable material is selected from a group of porous media consisting of ceramic, polymer, metal, stainless steel wool, and filtration media.

In some examples, the permeable material includes a density gradient.

In some examples, the insert includes a plurality of segments, and each segment includes a material to block flow of gas, a material to freely allow flow of gas, or the permeable material.

In some examples, the insert further includes a gas output slit disposed in a first side. The gas output slit has a non-rectangular shape to promote even flow of gas with respect to a width of the SALD head.

A further aspect of the specification provides a SALD head including at least one chamber configured to receive any of the above-described inserts.

A further aspect of the specification provides an apparatus including a plurality of SALD heads. The SALD heads include respective input faces configured to receive a gas and respective output faces configured to convey the gas onto a flexible substrate. The SALD heads are arranged in a compact adjacent spatial relationship with respect to a conveyance subsystem that is configured to convey the flexible substrate past the SALD heads. The compact adjacent spatial relationship is configured to provide an even distribution of gas by the SALD heads to the flexible substrate.

In some examples, the compact adjacent spatial relationship includes the SALD heads being circumferentially arranged around a roller of the conveyance subsystem. The output faces of the SALD heads are radially equidistant from a cylindrical surface of the roller.

In some examples, the output faces of the SALD heads are curved to match a curvature of the cylindrical surface of the roller.

In some examples, the compact adjacent spatial relationship includes SALD heads that are longitudinally stacked along a width of the flexible substrate.

In some examples, the compact adjacent spatial relationship includes SALD heads that are longitudinally and laterally offset from one another.

In some examples, the apparatus includes a manifold to distribute gas to the SALD heads. The manifold rigidly supports the SALD heads.

In some examples, the SALD head has a rigid monolithic construction.

In some examples, the SALD head is 3D printed.

In some examples, the conveyance subsystem is configured to air cushion the flexible substrate.

In some examples, the SALD apparatus includes a positive pressure enclosure that surrounds the SALD heads.

In some examples, at least one of the SALD heads further includes a permeable material disposed between the input face and output face and configured to convey the gas from the input face to the output face.

In some examples, the permeable material includes one or more of: a particulate, a lattice structure, a mesh, and a porous media.

In some examples, the permeable material includes one or more of the following particulates: stainless steel balls, glass beads, glass microspheres, fiberglass, cellulose, grains, sand, powders, granules, dust, crushed rock, crystals, metal shavings, and pellets.

In some examples, the permeable material includes one or more of the following porous media: ceramic, polymer, metal, stainless steel wool, and filtration media.

In some examples, the permeable material includes a density gradient.

In some examples, the permeable material is disposed in a removable insert.

In some examples, the removable insert includes a plurality of segments, and each segment includes a material to block flow of gas, a material to freely allow flow of gas, or the permeable material.

In some examples, the SALD head further includes a plurality of gas channels, each gas channel configured to provide a gas to a respective one of the plurality of segments.

In some examples, the SALD head further includes a plurality of chambers for receiving a plurality of respective inserts, including the removable insert.

In some examples, the SALD head further includes a gas output slit disposed in the output face, wherein the gas output slit has a non-rectangular shape to promote even flow of gas with respect to a width of the SALD head.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 is a schematic diagram of an example spatial atomic layer deposition (SALD) apparatus.

FIG. 2 is a cross-section of a SALD head comprising a permeable material, according to one embodiment.

FIG. 3A is a cross-section of the permeable material of FIG. 2, according to one embodiment.

FIG. 3B is a cross-section of the permeable material of FIG. 2, according to another embodiment.

FIG. 3C is a cross-section of the permeable material of FIG. 2, according to yet another embodiment.

FIG. 3D is a cross-section of the permeable material of FIG. 2, according to a further embodiment.

FIG. 4 is a cross-section of a segmented SALD head, according to one embodiment.

FIG. 5A is a cross-section of a SALD head, according to another embodiment.

FIG. 5B is a cross-section of a segmented SALD head, according to a further embodiment.

FIG. 6 is a cross-section of a segmented SALD head, according to yet another embodiment.

FIG. 7 is a cross-section of the SALD head having a plurality of inserts, according to one embodiment.

FIG. 8 is a cross-section of the SALD head having a plurality of inserts, according to another embodiment.

FIG. 9A is a perspective view of the SALD head having rod-shaped inserts, according to one embodiment.

FIG. 9B is a perspective view of the SALD head having a rectangular insert, according to one embodiment.

FIG. 10A is a bottom view of the SALD head having an output slit according to one embodiment.

FIG. 10B is a bottom view of the SALD head having an output slit according to another embodiment.

FIG. 10C is a bottom view of the SALD head having an output slit according to yet another embodiment.

FIG. 10D is a bottom view of the SALD head having an output slit according to a further embodiment.

FIG. 10E is a bottom view of the SALD head having an output slit according to yet a further embodiment.

FIG. 11A is a bottom view of a slit plate having an output slit according to one embodiment.

FIG. 11B is a bottom view of a slit plate having an output slit according to another embodiment.

FIG. 11C is a bottom view of a slit plate having an output slit according to yet another embodiment.

FIG. 11D is a bottom view of the slit plate according to a further embodiment.

FIG. 11E is a bottom view of the slit plate according to yet a further embodiment.

FIG. 12A is a bottom view of the SALD head according to one embodiment.

FIG. 12B is a bottom view of the SALD head according to another embodiment.

FIG. 13A is a side view of a SALD apparatus including a plurality of SALD heads arranged in a compact adjacent spatial relationship, according to one embodiment.

FIG. 13B is a side view of one of the SALD heads of FIG. 13A.

FIG. 14 is a top view of a SALD apparatus according to one embodiment.

FIG. 15 is a top view of a SALD apparatus according to another embodiment.

FIG. 16 is a cross-section of a SALD manifold according to one embodiment.

### DETAILED DESCRIPTION

The following abbreviations are used herein:

| | |
|---|---|
| DEZ | Diethyl Zinc |
| SALD | Spatial Atomic Layer Deposition |
| TMA | Trimethylaluminum |

The present disclosure provides a SALD apparatus, a SALD head, and a removable insert for evenly distributing gas in a SALD apparatus.

The present invention will be described with respect to the figures herein.

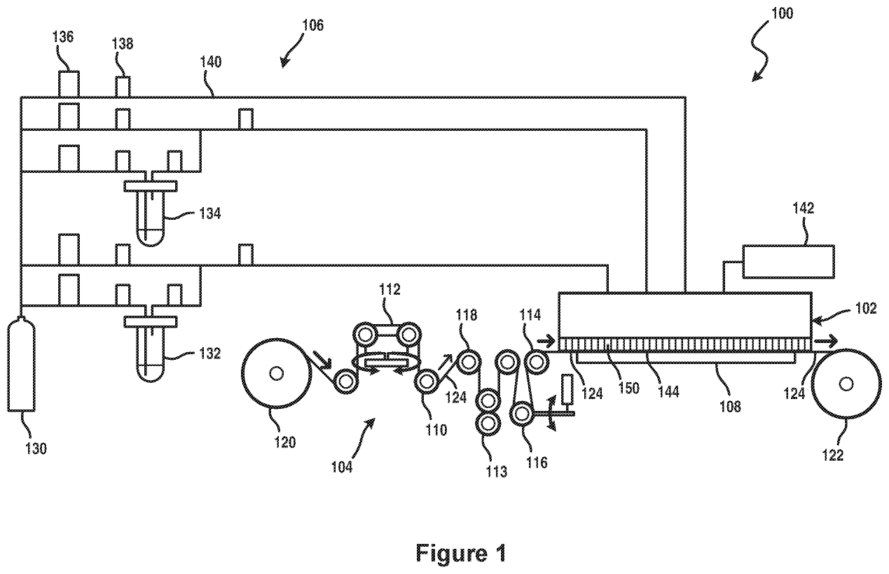

FIG. 1 is a schematic diagram of an example spatial atomic layer deposition (SALD) apparatus 100 operable to deposit a coating. The SALD apparatus 100 includes a SALD head 102, a conveyance system 104, and a gas-delivery system 106. A heater 108 may be provided at the SALD head 102. Any suitable number of SALD heads 102 may be used to deliver any suitable combination of gases by the gas-delivery system 106 to deposit a coating onto a flexible substrate conveyed past the SALD head 102 by the conveyance system 104. The flexible substrate may be conveyed in one or both directions past one or multiple SALD heads 102 to build up the coating.

The conveyance system 104 may include rollers 110, web guides 112, nip rollers 113, idlers 114, dancers 116, load cells 118, and like components positioned between an unwinder 120 and a winder 122 to convey a flexible substrate material 124, such as a thin sheet or membrane of material (sometimes called a “film,” particularly in the packaging industry, but this is not to be confused with the thin film or coating being deposited). With the conveyance system 104, the flexible substrate material 124 may be unwound from a roll at the unwinder 120, coated by the SALD head 102, and wound onto another roll at the winder 122. The positioning of the rollers may be used to position flexible material relative to one or more SALD heads 102 and may be used to control the distance between the surface of the flexible material 124 and the surface of the SALD head 102.

The gas-delivery system 106 includes vessels 130, 132, 134 with inert gas (e.g., nitrogen), precursor (e.g., TMA, DEZ, Al(CH3)3), and reactant (e.g., an oxidant such as H2O), mass flow controllers 136, on-off valves 138, and gas lines 140 that fluidly connect these components. Each gas line 140 may deliver to the SALD head 102 pure or a mixture of an inert gas, precursor, and reactant, at a flow rate controlled by respective mass flow controller(s) 136 and on-off valve(s) 138. The configuration and arrangement of the components in FIG. 1 represent an example. In other examples, the components may have different configurations and arrangements.

The gas lines 140 may be tubes made of chemically stable or inert material, such as stainless steel or Teflon, connected between components upstream of the SALD head 102. Such components may include an inert gas vessel 130, chemical-containing vessels (e.g., bubblers) 132, 134, mass flow controllers 136, and on-off valves 138. This gas-delivery system 106 serves the purpose of delivering one or more precursor gases, one or more reactant gases, and one or more inert gases, in pure form or suitable mixtures, to the SALD head 102. The inert gas vessel 130 supplies inert, non-reactive gas to the SALD head 102 and may also be used to carry precursor gas from a precursor gas vessel 134 and/or reactant gas from a reactant gas vessel 132 to the SALD head 102. The pressure of the inert gas may be regulated by one or more pressure regulators. The precursor and reactant gases may be generated by techniques such as, but not limited to, bubbling a liquid chemical with the inert gas, nebulizing a liquid chemical, by heating a liquid or solid chemical, direct liquid injection where a liquid chemical precursor is introduced to a vaporizer which vaporizes the liquid and ejects gas out of a nozzle, or a combination thereof. Chemical vapors may also be supplied in the gaseous state from a storage tank, or generated by another device, such as an ozone generator, which may be used to generate a reactant gas. The flow rates of the inert gas, one or more precursor gases, and one or more reactant gases are controlled by mass flow controllers 136 and on-off valves 138, such as manual diaphragm valves or pneumatic valves. The mass flow controllers 136 and valves 138 may be controlled manually or electronically by a control system.

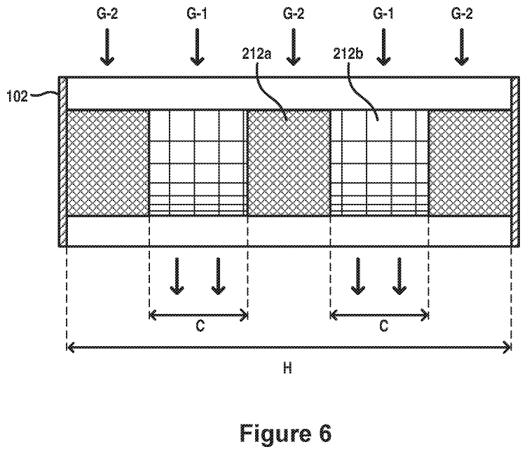

As illustrated in FIG. 1, one or more SALD heads 102 deliver a precursor, reactant, and inert gas onto a flexible substrate material 124. The SALD head 102 comprises multiple internal gas channels that redirect and distribute the gases out onto the flexible material 124 in an appropriate arrangement to result in SALD, as illustrated in FIG. 6. The SALD head 102 includes any suitable number and configuration of outlets 150 to output gas to the flexible substrate material 124. Other components may be integrated into one or more SALD heads 102, including, but not limited to, cooling and heating elements and plasma sources. For example, one or more plasma sources may be embedded into the head to lower the temperature required for the coating deposition. According to FIG. 1, one or more exhaust pumps 142 are connected to the SALD head 102. The exhaust pump 142 removes gases such as unreacted precursor and/or reactant and inert gas from the space between the operating surface 144 of the SALD head 102 and the surface of the flexible material 124.

Illustrated in FIG. 1, the heater 108 may be used to heat the flexible material 124 to facilitate chemical reactions on the surface of the flexible material 124. In the example shown, the heater 108 spans the length of the SALD head 102. Various heaters with different heating power and with different shapes and sizes (e.g., a drum heater that the flexible material wraps around) may be provided. Additionally, one or more heaters may be embedded into the SALD head 102. One or more heaters may also be used to control the position of the surface of the flexible material relative to one or more of the SALD heads 102, based on the mechanical positioning of the heater(s). One or more of the rollers of the conveyance system 104 may be heated to control the temperature of the flexible material 124.

In other examples, a sheet or multiple sheets of flexible material can be mounted on a translating stage which moves past the head either in a single-direction or in both directions for the coating process. The translating stage may be heated and may be used to control the distance between the surface of the flexible material and the surface of a SALD head 102.

More information concerning examples of the gas delivery system, SALD head(s), exhaust pump(s), heater(s), and translating stage can be found in PCT publication WO2021119829, which is incorporated herein by reference.

With reference to the general SALD system of FIG. 1, various techniques are discussed herein to reduce the overall size and increase the overall efficiency of a continuous coating deposition system. It is contemplated that, in various implementations, tens or hundreds of individual SALD heads may be used to dispose a coating to a flexible substrate. Compactness, modularity, maintainability, and efficiency are thus important considerations. Compactness in the direction of substrate movement is an important factor in reducing production line size. In a system with, for example, 500 SALD heads, reducing the space required for a single SALD head by 0.5 cm in the direction of substrate conveyance may reduce the overall size of the coating portion of the line by 2.5 m (500×0.025 m). This helps reduce the footprint of new line installations and also helps when retrofitting existing lines.

Discussed herein are example SALD apparatuses that include SALD heads arranged in a compact adjacent spatial relationship with respect to a conveyance subsystem that is configured to convey a flexible substrate past the SALD heads. In various examples, the compact adjacent spatial relationship is configured to provide an even distribution of gas by the SALD heads to the flexible substrate. The internals of SALD head may include configurable inserts, lattice structures, and porous materials to help evenly distribute gas. Various other improvements will also be discussed.

The SALD heads discussed herein may have a rigid monolithic construction. Rigid monolithic construction provides for stiffness that helps ensure proper coating. Various techniques are described herein to provide for an accommodate rigid monolithic construction. The SALD heads discussed herein may be 3D printed with post printing machining at the output face. Suitable 3D printers include multi-jet printing devices sold by 3D Systems™ (www.3dsystems.com). Suitable resin includes VisiJet™ HT-90 resin, which is useful due to its tolerance to 60 °C operational temperature that is expected for the SALD heads discussed herein. Other manufacturing techniques may be used, such as diffusion bonding, sheet metal stamping, and gluing several base parts together.

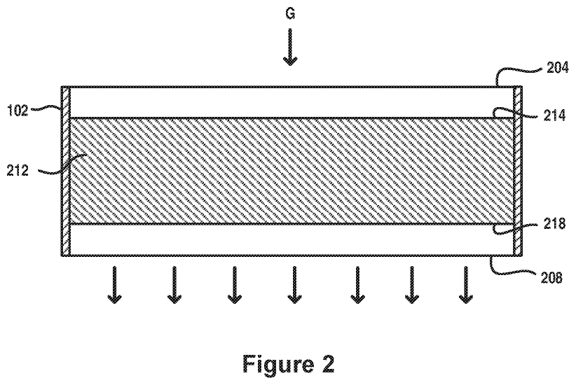

FIG. 2 shows a cross-section of the SALD head 102, according to one non-limiting embodiment. The SALD head 102 comprises an input face 204 for receiving gas G from the gas lines 140 and an output face 208 for outputting gas onto the flexible material 124. Disposed between the input face 204 and output face 208 is a permeable material 212, such that gas passing from the input face 204 to the output face 208 passes through the permeable material 212. The permeable material 212 generally has a first end 214 proximal the input face 204 and configured to receive gas via the input face 204, and a second end 218 opposite the first end 214 and configured to transfer gas to the output face 208. Generally, the permeable material 212 slows the flow of gas through the SALD head 102 which helps to evenly distribute gas from the output face 108. This may be advantageous for distributing gas over large coating areas, without discontinuities.

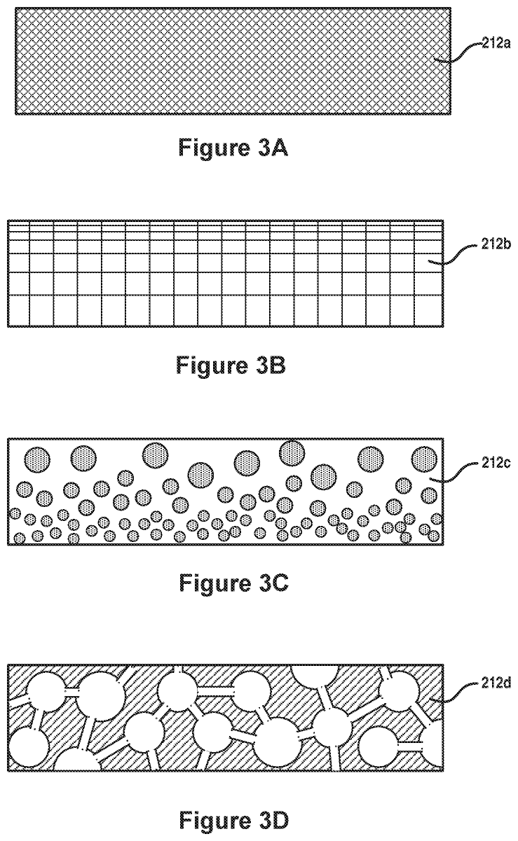

The permeable material 212 may comprise a mesh or lattice structure. The mesh or lattice structure may be 3D-printed, machined, etched, sintered, or any other method known in the art. FIGS. 3A, 3B illustrate examples of the permeable material 212a, 212b comprising a lattice structure.

The permeable material 212 may comprise a particulate including but not limited to stainless steel balls, glass beads, glass microspheres, fiberglass, cellulose, grains, sand, powders, granules, dust, crushed rock, crystals, metal shavings, pellets, and a combination thereof. In some examples, the particulate comprises particles having uniform sizes and shapes. In other examples, the particulate comprises particulates having a mixture of sizes and shapes. FIG. 3C illustrates an example of the permeable material 212c comprising a particulate.

The permeable material 212 may comprise a porous media including but not limited to a ceramic, a polymer, a metal (such as porous aluminum), stainless steel wool, a sponge, paper, cardboard, and a filtration media. In specific, non-limiting examples, the porous media comprises a 3D-printed material with intentional gaps or holes. In other non-limiting examples, the porous media comprises stacked layers of porous sheets, such as paper or cardboard. It may be advantageous for the pores to be evenly sized and/or evenly distributed throughout the porous media. FIG. 3D illustrates an example of the permeable material 212d comprising a porous material.

Herein, the permeable materials 212a, 212b, 212c are referred to generally as “permeable material 212”, or collectively as “permeable materials 212”.

The density of the permeable material 212 may be selected according to the desired effect. In examples where the density is relatively high compared to the surrounding space for gas to flow in the SALD head 102, the permeable material may primarily influence the pressure component of the mass flow rate of the gas. In examples where the density is relatively low compared to the surrounding space for gas to flow in the SALD head 102, the permeable material may primarily influence the velocity component of the mass flow rate of the gas. Generally, particulate materials are high density, whereas mesh and lattice structures are typically low-density materials, however exceptions exist.

The density of the permeable material 212 may be uniform or non-uniform. In examples where the density is non-uniform, the permeable material may be graded across the length, width, or height. An example of a graded permeable material is shown in FIG. 3B which shows a lattice with a density gradient extending across the height of the permeable material. The density of the permeable material 212b is highest at the first end 214 and lowest at the second end 218. Another example of a density gradient is shown in FIG. 3C which shows a graded particulate. The density of the permeable material 212c is highest at the second end 218 where the particles are smallest and lowest at the first end 214 where the particles are largest. A skilled person will understand that gradients are not particularly restricted to lattice and particulate materials and in other examples, a gradient may be achieved with a porous material or mesh. Furthermore, while the permeable material 212 has been depicted with a lengthwise gradient extending from the first end 214 to the second end 218, the density may instead vary widthwise, with the gradient extending across the width of the SALD head 102.

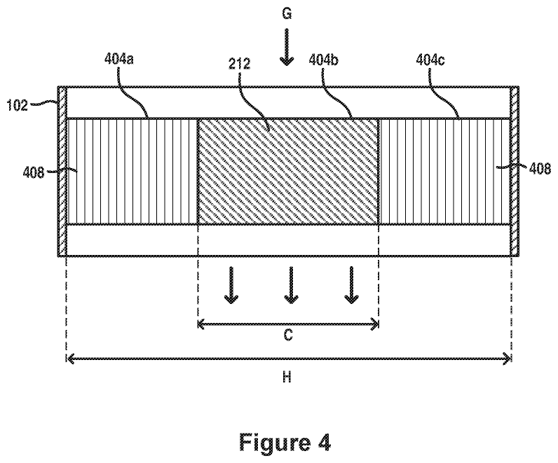

In the examples shown and described above, the permeable material 212 extends across an internal width and length of the SALD head 102, however the permeable material 212 is not particularly limited. In some examples, the SALD head is segmented. One example of a segmented SALD head is shown in FIG. 4, which shows a cross-section of the SALD head 102 according to one embodiment. In this embodiment, the internal width of the SALD head H is divided into a plurality of segments 404a, 404b, 404c (referred to generally as “segment 404” or collectively as “segments 404”). At least one of the segments 404 comprises the permeable material 212. One of the segments 404 may comprise a blocking material 408 configured to block the flow of gas. In specific examples, the blocking material is impermeable to air. One of the segments 404 may comprise a material to freely allow the flow of gas. In some examples, two or more of the segments 404 comprise permeable materials 212 with differing characteristics. For example, the segments may differ in structure, density, density gradient, or the like. Generally, the permeability of each segment varies, resulting in air flow that varies across the internal head width H.

In the example shown in FIG. 4, segment 404b comprises the permeable material 212, and the remaining segments 404 comprise the blocking material. As a result of the blocking area, a selective area of the flexible is coated with the precursor gas, as defined by the coating width C of the SALD head 102. The coating width C is less than the internal head width H. This arrangement is suitable for coating an area that is narrower than the internal head width H of the SALD apparatus 100. In a specific, non-limiting example, the internal head width H is 1 meter, and the coating width C is 0.6 meters.

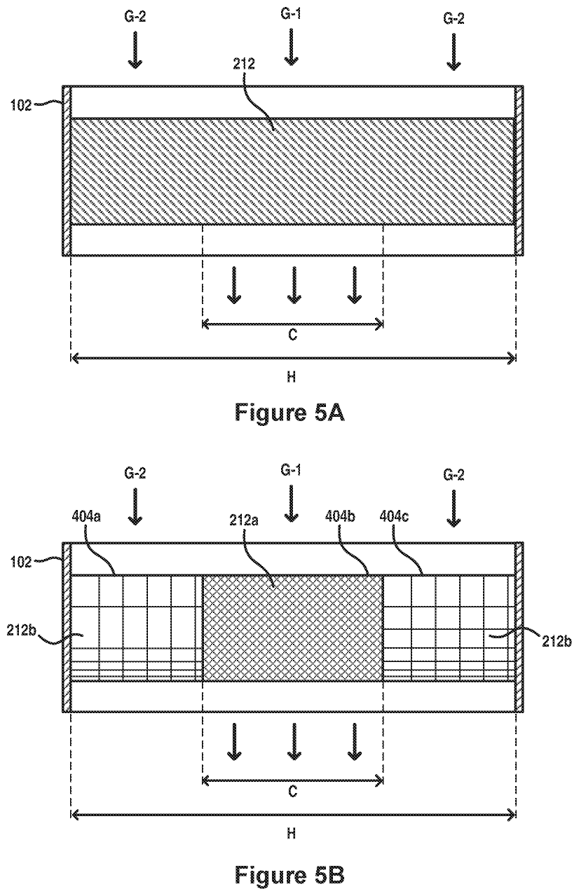

Another way to control the coating width C is with inert gases. As shown in FIG. 5A, more than one gas is provided to the SALD head 102 via the gas lines. The SALD head 102 may further include gas channels arranged to direct the more than one gas to a respective portion of the porous media 212. In this example, a precursor gas G-1 is directed through the middle of the porous media 212 and an inert gas G-2 is directed through the outer portions of the porous media 212. Consequently, the precursor gas is applied only to the coating width C of the flexible substrate. Furthermore, the inert gas G-2 can prevent the precursor gas from mixing with air, enabling the SALD head 102 to be used in environments other than vacuum chambers. To improve control over the coating width C and prevent the precursor gas G-1 from spreading, the inert gas G-2 may be delivered at a higher air pressure and/or flow rate as compared to the precursor gas G-1.

Control over the coating width C may be further improved by segmenting the permeable material. FIG. 5B is a cross-section of the SALD head 102 according to another embodiment. The segments 404 comprise more than one type of permeable material 212. In particular, segments 404a and 404c comprise a first permeable material 212b and segment 404b comprises a second permeable material 212a. Like FIG. 5A, more than one gas is provided to the SALD head 102 via the gas lines. The permeable materials may be selected to control the flow rate of each gas. In particular examples, the first permeable material 212b has a lower density than the second permeable material 212a, which increases the flow rate of the inert gas G-2 and limits the unintended spread of precursor gas G-1. The pressure of the inert and precursor gases may be further controlled to more precisely control the coating width C.

The SALD head 102 may include any suitable number of segments 404. FIG. 6 is a cross-section of another example of a segmented SALD head. In this example, the SALD head includes 5 segments. The inert gas G-2 can prevent mixing between precursor gases G-1 delivered through different segments of the SALD head 102 and can further prevent mixing between the precursor gas G-1 and other gases delivered by the SALD head such as reactant or co-reactant gases. A skilled person will now understand that any suitable number of segments may be included in the SALD head, and that the segments may be selected according to the desired properties of the coating.

The permeable material 212 may be housed in a removable insert. In embodiments where the SALD head 102 is segmented, the segments 404 may be further housed in the insert. Generally, the insert is selected according to the desired air flow characteristics and coating width. The selected insert is inserted into a corresponding chamber in the SALD head 102. The inserts improve the ease of maintaining and cleaning the SALD head 102, as the insert may be cleaned and replaced or exchanged with a fresh insert. Removing and replacing an insert is also less likely to disturb the precise positioning of the output face of the SALD head 102. It should be understood that any of the permeable materials 212 described above may be provided in a removable insert.

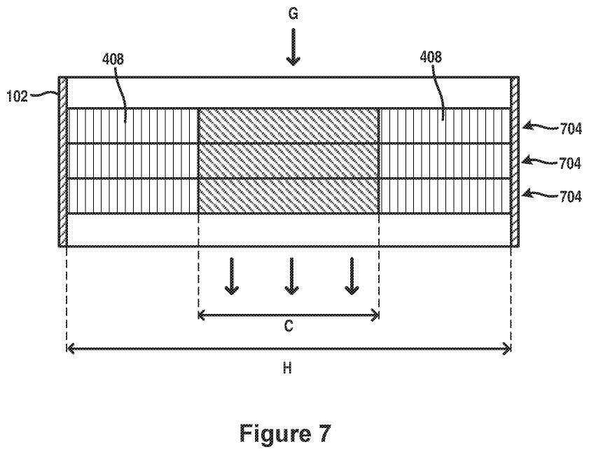

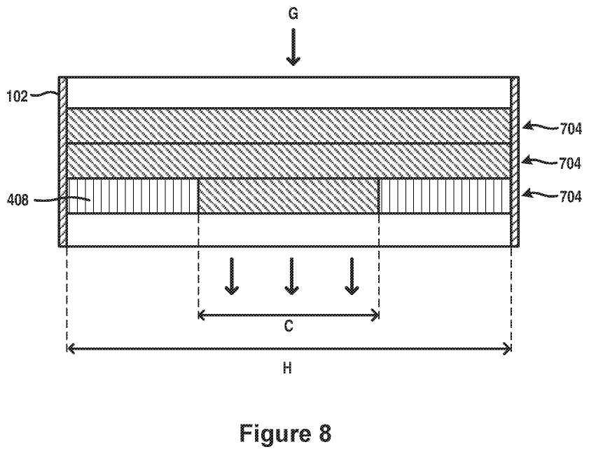

The SALD head 102 may comprise one or more corresponding chambers for receiving a plurality of inserts. In embodiments where the SALD head 102 is configured to receive a plurality of inserts, various combinations of inserts may be inserted to control the characteristics of the gas flow. FIG. 7 is a cross-section of the SALD head 102 according to one embodiment having a plurality of inserts 704. In this embodiment, three inserts 704 are inserted in the SALD head 102, however the SALD head 102 is not particularly limited, and the SALD head 102 may be configured to receive any suitable number of inserts 704. The inserts 704 shown in FIG. 7 include segments of the blocking material 408 surrounding the permeable material 212, such that gas flows through the effective coating width C. Each of the inserts 704 shown in FIG. 7 has congruent segments, however the inserts 704 are not particularly limited. In other examples, such as the example shown in FIG. 8, the inserts 704 have varying configurations. FIG. 8 is a cross-section of the SALD head 102 according to another embodiment. In this embodiment, two of the inserts 704 are unsegmented and comprise only the permeable material 212, while the third insert 704 is segmented with the blocking material 408. Consequently, gas is funneled through the coating width C.

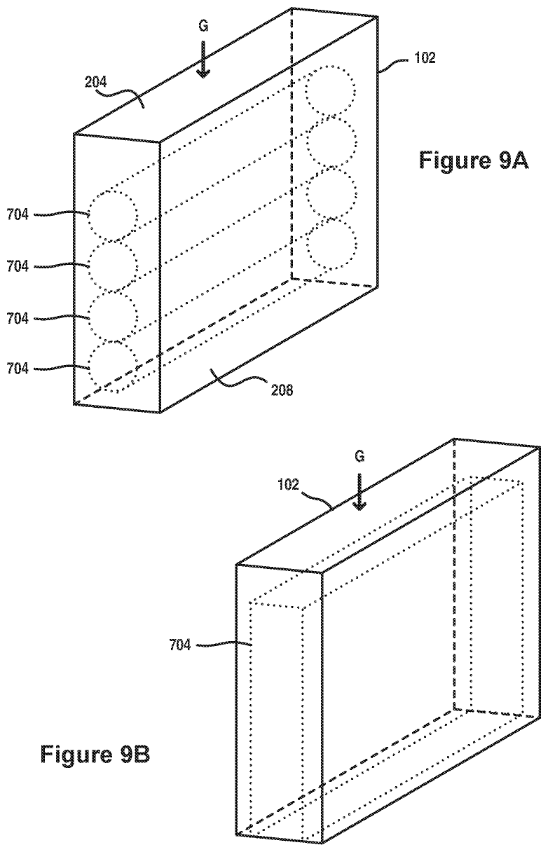

The shape of the insert 704 is not particularly limited. FIG. 9A is a perspective view of the SALD head 102 according to one embodiment. In FIG. 9A, the inserts 704 are rod shaped. FIG. 9B is a perspective view of the SALD head 102 according to another embodiment. In FIG. 8B, the insert 704 has the shape of a rectangular prism.

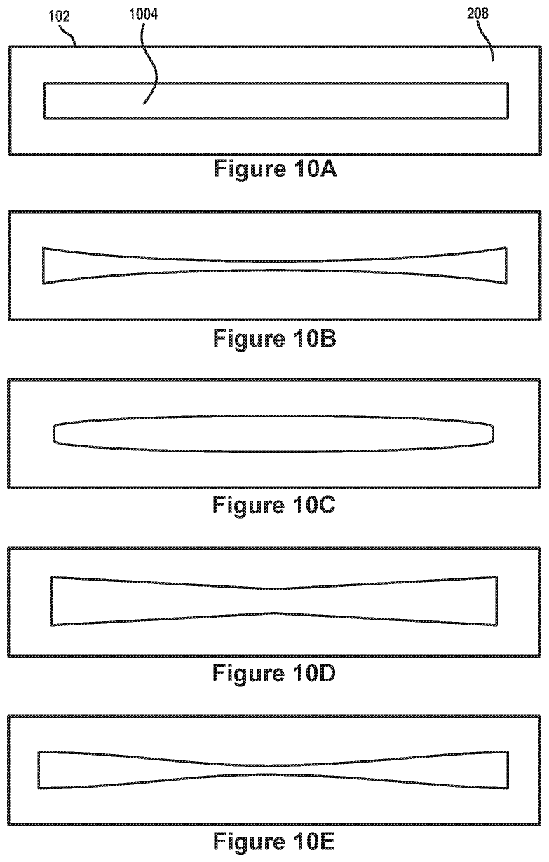

FIG. 10A is a bottom view of the SALD head 102, according to one embodiment. The SALD head 102 includes an output slit 1004 in the output face 208 for transmitting the gas to the flexible substrate material 124. In some examples, the output face 208 includes a plurality of output slits 1004.

Exemplary variations on the output slit 1004 are shown in FIGS. 10A to 10E, but the shape and dimensions of the output slit 1004 are not particularly limited. The depictions in FIGS. 10A to 10E are exaggerated in size, particularly with regard to the width of the output slit 1004, for sake of explanation. The examples shown in FIGS. 10A to 10E are symmetrical, however the output slit 1004 is not particularly limited. In other examples, the output slit is wider at one end than an opposite end so as to create a non-uniform coating. In other examples, the gas channel is positioned to direct the gas towards one end of the SALD head 102, which can cause the coating to be thicker towards that side. In these examples, the output slit may be asymmetrical to compensate for the positioning of the gas channel and produce a uniform coating. In further examples, the outlet may be asymmetrical to control the selective area of deposition.

FIG. 10A shows a rectangular output slit and FIGS. 10B to 10E show non-rectangular output slits. FIG. 10B shows a bi-concave output slit with curvature that narrows towards the middle, which may be useful to encourage gas to exit the slit towards the ends. FIG. 10C shows a biconvex gas output slit with curvature that narrows towards the ends, which may be useful to encourage gas to exit the output slit towards the middle. FIG. 10D shows a bowtie-shaped gas output slit with a linear shape that narrows towards the middle, which may be useful to encourage gas to exit the slit towards the ends. FIG. 10E shows an hourglass-shaped output slit with curvature that narrows towards the middle, which may be useful to encourage gas to exit the output slit towards the ends. A widened region of the output slit may encourage gas to exit the slit at that region by way of reduced flow resistance. Such a widened region may be placed at a location expected to have reduced gas flow due to internal structure of the head, manifold, flow paths, etc. Numerous other examples of such output slits are contemplated.

Non-rectangular output slits promote even flow of gas with respect to a length of the SALD head 102. The output slit 1004 may be wider at its ends, as shown in FIGS. 10B, 10D, 10E, to reduce resistance to low at the ends, thereby encouraging flow to the ends which may otherwise receive insufficient amounts of gas.

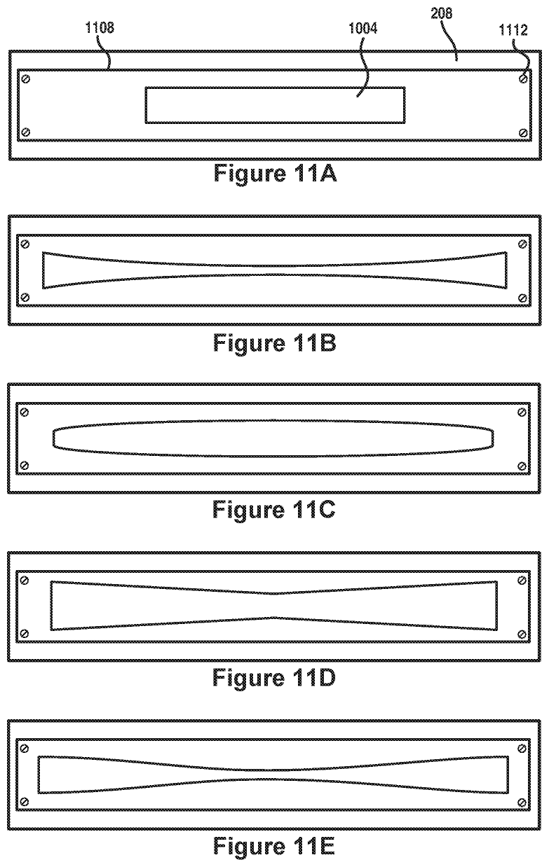

The shape and dimensions of the output slit 1004 may be modified with a detachable slit plate 1108. FIGS. 11A to 11F show several variations of the detachable slit plate 1108. The detachable slit plate 1108 may be detachably connected to the SALD head 102 with an attachment means 1112. Non-limiting examples of attachment means include fasteners, welding, adhesive bonding, brazing, interference fit, threading, clamping, soldering, and combinations thereof.

In any of the above-described examples, the removable insert may be connected to or continuous with the detachable slit plate, allowing both the slit plate and the permeable material 212 to be selected when the insert is exchanged. In particular examples, the slit plate includes a slot for receiving the removable insert.

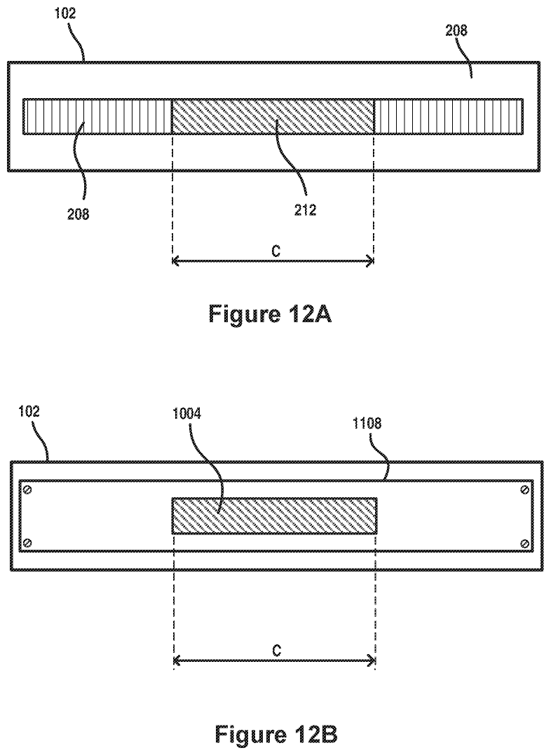

A person of skill in the art should now understand that the air flow in the SALD head 102 can be controlled either with the permeable material 212, or the output slit 1004, or a combination thereof. The concept is exemplified in FIGS. 12A and 12B, which show bottom views of the SALD head 102. In FIG. 12A, the SALD head 102 is segmented with the blocking material 408, such that the coating width is the width of the permeable material 212. FIG. 12B demonstrates that the coating width C can be similarly controlled by connecting a detachable slit plate 1108 to the output face 208. The modularity of the removable insert and detachable slit plate greatly increases the number of possible configurations available in the SALD process.

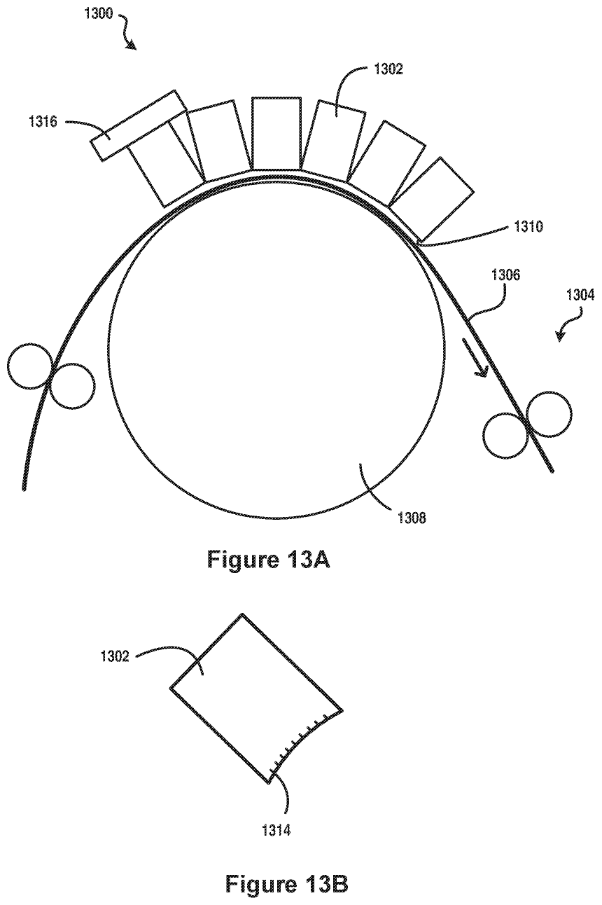

FIG. 13A shows an example apparatus 1300 that includes SALD heads 1302 arranged in a compact adjacent spatial relationship with respect to a conveyance subsystem 1304 that is configured to convey a flexible substrate 1306 past the SALD heads 1302. The compact adjacent spatial relationship is configured to provide an even distribution of gas by the SALD heads 1302 to the flexible substrate 1306.

The conveyance subsystem 1304 includes a cylindrical roller 1308 over which the flexible substrate 1306 is conveyed. The roller 1308 may provide an air (or other gas, generally termed “air”) cushion subsystem to reduce risk of damaging the flexible substrate 1306 or coating disposed thereon (e.g., the roller side of the substrate may be coated as well). Other components of the conveyance subsystem 1304, such as other rollers, may be air cushioned as well. Air cushioning reduces or eliminates direct contact of the flexible substrate 1306 to the component to reduce or eliminate scratching, rubbing, or other damage to the flexible substrate 1306. In addition, or alternatively, a roller, such as the roller 1308, may be driven at a speed that reduces or eliminates a differential in speed between the surface of the component and the flexible substrate 1306. For example, the roller 1308 may be driven at a rotational speed that causes the linear speed of the surface of the roller 1308 to closely or exactly match the linear speed of the flexible substrate 1306. This may also reduce or eliminate scratching or other damage to the flexible substrate 1306.

The compact adjacent spatial relationship of SALD heads 1302 includes a circumferential arrangement of SALD heads 1302 around the roller 1308. The gas-output faces 1310 of the SALD heads 1302 are radially equidistant from the cylindrical surface of the roller 1308 to promote even and predictable deposition of coating material.

FIG. 13B shows the SALD heads 1302 in greater detail. The gas-output faces 1310 of the SALD heads 1302 may be curved, to match a curvature of the cylindrical surface of the roller 1308. This allows each slit 1314 in the gas-output face 1310 to be equidistant from the roller 1308. Furthermore, SALD heads 1302 may be arranged such that the slits 1314 are perpendicular to a plane tangent to the curved surface of the roller 1308.

Returning to FIG. 13A, a backing structure 1316 (partially shown) may be provided to support the SALD heads 1302. The backing structure may be used as a datum to assist in precisely locating the SALD heads 1302. In various examples, the radial distance from the gas-output face 1310 to the flexible substrate 1306 is 1 mm or less. Shims, adjustable plates positionable by set screws, springs, pneumatics, or similar mechanism/structure may be used to fine-tune the position of a SALD head 1302.

The radial arrangement of SALD heads 1302 provides for compactness that may reduce the overall footprint required.

The apparatus 1300 may include a positive pressure enclosure that surrounds the SALD heads 1302. Positive pressure may be provided by gas, such as nitrogen, that is used in the SALD process. Positive pressure may be relatively low.

The apparatus 1300 may be implemented as a module. A modular apparatus may thus be formed of one or more apparatuses 1300. For example, a module implementation of the apparatus 1300 may include one hundred SALD heads 1302 circumferentially arranged around the roller 1308 to deposit a coating with a total nominal thickness of 10 nm. Five such module implementations of the apparatus 1300 may be arranged on a line, so as to deposit a coating with a total nominal thickness of 50 nm.

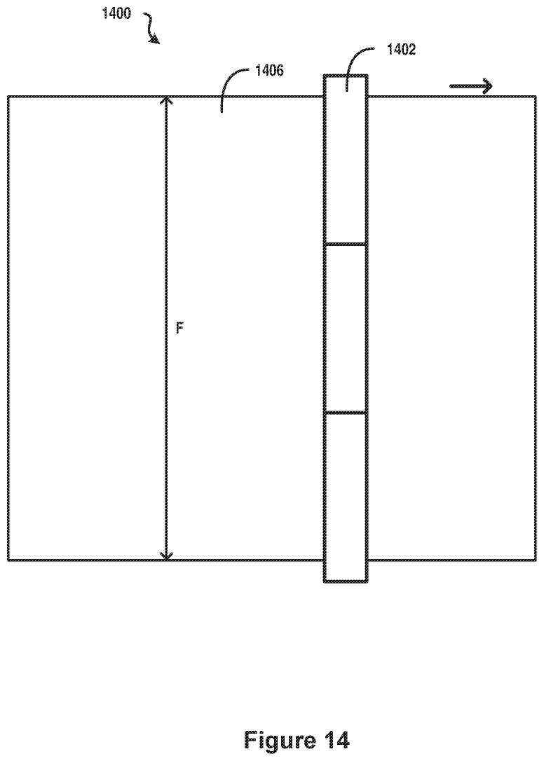

FIG. 14 shows an example apparatus 1400 that includes SALD heads 1402 arranged in a compact adjacent spatial relationship with respect to a conveyance subsystem that is configured to convey a flexible substrate 1406 past the SALD heads 1402. The compact adjacent spatial relationship is configured to provide an even distribution of gas by the SALD heads 1402 to the flexible substrate 1406.

In this example, the compact adjacent spatial relationship includes SALD heads 1402 that are longitudinally stacked along a width F of the flexible substrate 1406. Longitudinal stacking may be useful to allow several short SALD heads 1402 to evenly coat a wider substrate. Undesired flexure towards or away from the flexible substrate 1406 may be more readily controlled with a shorter SALD head. Controlling flexure helps ensure precise and consistent location of the gas-output faces of the SALD heads with respect to the flexible substrate 1406 (e.g., 1 mm or less spacing). Printed segments are typically up to 300 mm long, so 3-4 SALD heads 1402 are required to coat a 1-m wide film.

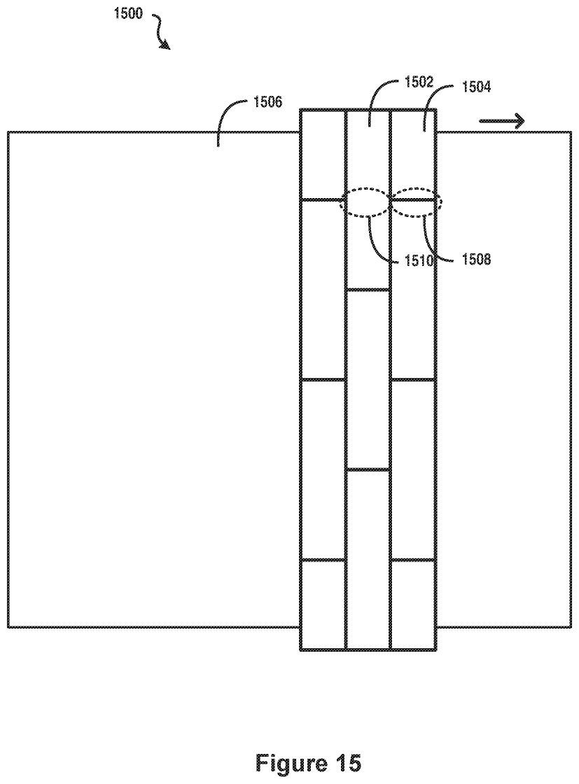

FIG. 15 shows an example apparatus 1500 that includes SALD heads 1502, 1504 arranged in a compact adjacent spatial relationship with respect to a conveyance subsystem that is configured to convey a flexible substrate 1506 past the SALD heads 1502, 1504. The compact adjacent spatial relationship is configured to provide an even distribution of gas by the SALD heads 1502, 1504 to the flexible substrate 1506.

In this example, the compact adjacent spatial relationship includes SALD heads 1502, 1504 that are longitudinally and laterally offset from one another. This arrangement may be considered a brickwork pattern that may improve stiffness to maintain precise and consistent location of the gas-output faces of the SALD heads with respect to the flexible substrate 1506 (e.g., 1 mm or less spacing). Further, this arrangement may help smooth and discontinuities in the coating that may be caused by the transition region 1508 between longitudinally adjacent SALD heads 1502, 1504. If a transition region 1508 causes a flaw in the coating, such a flaw may be mitigated by the lack of a transition region (i.e., a continuous region), indicated at 1510, with the next SALD head. SALD heads 1502, 1504 of different lengths may be provided to achieve the longitudinally and laterally (brickwork) pattern.

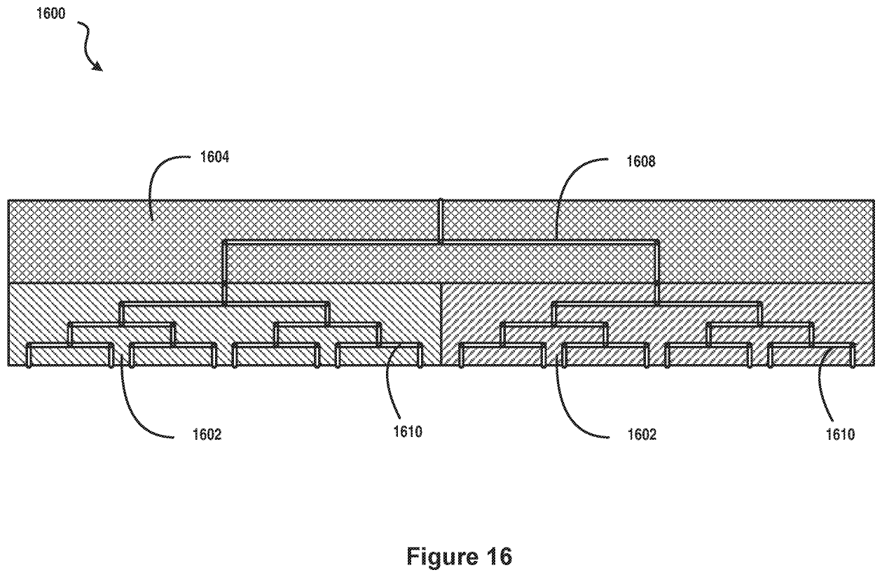

FIG. 16 shows an example apparatus 1600. The apparatus 1600 includes assembly of SALD heads 1602 arranged longitudinally (end-to-end). The apparatus 1600 further includes a manifold 1604 to distribute gas to the SALD heads 1602. The manifold 1604 is positioned above the SALD heads 1602 to rigidly support the SALD heads 1602 against flexure towards or away from the flexible membrane. The manifold 1604 includes gas channels 1608 that communicate with gas channels 1610 of the SALD heads 1602 to distributed gas. Any number and configuration of manifolds 1604 may be used. In the example shown, the manifold is continuous over the discontinuous transition between the SALD heads 1602, which increases rigidity of the apparatus 1600.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. An atomic layer deposition (SALD) head configured to provide a gas to a flexible substrate, the SALD head comprising:
an input face configured to receive a gas;
an output face configured to convey the gas onto the flexible substrate; and
a permeable material disposed between the input face and the output face and configured to convey the gas from the input face to the output face, the permeable material configured to evenly distribute the gas with respect to a width of the SALD head.

2. The SALD head of claim 1, wherein the permeable material comprises one or more of: a particulate, a lattice structure, a mesh, and a porous media.

3. The SALD head of claim 1, wherein the permeable material comprises one or more of the following particulates: stainless steel balls, glass beads, glass microspheres, fiberglass, cellulose, grains, sand, powders, granules, dust, crushed rock, crystals, metal shavings, and pellets.

4. The SALD head of claim 1, where the permeable material comprises one or more of the following porous media: ceramic, polymer, metal, stainless steel wool, and filtration media.

5. The SALD head of any one of claims 1-4 wherein the permeable material comprises a density gradient.

6. The SALD head of any one of claims 1-5 wherein the permeable material is housed in a removable insert.

7. The SALD head of claim 6, wherein the removable insert comprises a plurality of segments and each segment comprises a material selected from a group of materials comprising:
a material to block flow of gas;
a material to freely allow flow of gas; and
the permeable material.

8. The SALD head of claim 7 further comprising a plurality of gas channels, each gas channel configured to provide a gas to a respective one of the plurality of segments.

9. The SALD head of any one of claims 6 to 8 wherein the SALD head comprises a plurality of chambers for receiving a plurality of respective inserts, including the removable insert.

10. The SALD head of claim 1 further comprising a gas output slit disposed in the output face, wherein the gas output slit has a non-rectangular shape to promote even flow of gas with respect to a width of the SALD head.

11. An insert for a SALD head, the insert configured to be inserted between an input face of the SALD head and an output face of the SALD head, the insert comprising:
a permeable material configured to slow the flow of gas from the input face to the output face and evenly distribute a gas with respect to a width of the SALD head.

12. The insert of claim 11, wherein the permeable material comprises one or more of: a particulate, a lattice, a mesh, and a porous media.

13. The insert of claim 11, wherein the permeable material comprises one or more of the following particulates: stainless steel balls, glass beads, glass microspheres, fiberglass, cellulose, grains, sand, powders, granules, dust, crushed rock, crystals, metal shavings, and pellets.

14. The insert of claim 11, where the permeable material is selected from a group of porous media consisting of ceramic, polymer, metal, stainless steel wool, and filtration media.

15. The SALD head of any one of claims 11-14 wherein the permeable material comprises a density gradient.

16. The insert of any one of claims 11-15, wherein the insert comprises a plurality of segments, and each segment comprises a material selected from a group of materials comprising:
a material to block flow of gas;
a material to freely allow flow of gas; and
the permeable material.

17. The insert of claim 16 further comprising a gas output slit disposed on a first side, wherein the gas output slit has a non-rectangular shape to promote even flow of gas with respect to a width of the SALD head.

18. A SALD head comprising at least one chamber configured to receive the insert of any one of claims 11-17.

19. An apparatus comprising:
a plurality of SALD heads comprising respective input face configured to receive a gas and respective output faces configured to convey the gas onto a flexible substrate, the SALD heads arranged in a compact adjacent spatial relationship with respect to a conveyance subsystem that is configured to convey the flexible substrate past the SALD heads;
wherein the compact adjacent spatial relationship is configured to provide an even distribution of gas by the SALD heads to the flexible substrate.

20. The apparatus of claim 19, wherein:
the compact adjacent spatial relationship includes the SALD heads being circumferentially arranged around a roller of the conveyance subsystem; and
output faces of the SALD heads are radially equidistant from a cylindrical surface of the roller.

21. The apparatus of claim 20, wherein the output faces of the SALD heads are curved to match a curvature of the cylindrical surface of the roller.

22. The apparatus of claim 19, wherein the compact adjacent spatial relationship includes SALD heads that are longitudinally stacked along a width of the flexible substrate.

23. The apparatus of claim 19, wherein the compact adjacent spatial relationship includes SALD heads that are longitudinally and laterally offset from one another.

24. The apparatus of claim 19, further comprising a manifold to distribute gas to the SALD heads, wherein the manifold rigidly supports the SALD heads.

25. The apparatus of claim 19, wherein a SALD head has a rigid monolithic construction.

26. The apparatus of claim 25, wherein the SALD head is 3D printed.

27. The apparatus of claim 19, wherein the conveyance subsystem is configured to air cushion the flexible substrate.

28. The apparatus of claim 19, further comprising a positive pressure enclosure that surrounds the SALD heads.

29. The apparatus of claim 19, wherein at least one of the SALD heads further comprises a permeable material disposed between the input face and output face and configured to convey the gas from the input face to the output face.

30. The apparatus of claim 29, wherein the permeable material comprises one or more of: a particulate, a lattice structure, a mesh, and a porous media.

31. The apparatus of claim 29, wherein the permeable material comprises one or more of the following particulates: stainless steel balls, glass beads, glass microspheres, fiberglass, cellulose, grains, sand, powders, granules, dust, crushed rock, crystals, metal shavings, and pellets.

32. The apparatus of claim 29, where the permeable material comprises one or more of the following porous media: ceramic, polymer, metal, stainless steel wool, and filtration media.

33. The apparatus of any one of claims 29-32 wherein the permeable material comprises a density gradient.

34. The apparatus of any one of claims 29-33 wherein the permeable material is disposed in a removable insert.

35. The apparatus of claim 34, wherein the removable insert comprises a plurality of segments and each segment comprises a material selected from a group of materials comprising:
a material to block flow of gas;
a material to freely allow flow of gas; and
the permeable material.

36. The apparatus of claim 35, wherein the at least one SALD head further comprises a plurality of gas channels, each gas channel configured to provide a gas to a respective one of the plurality of segments.

37. The apparatus of any one of claims 34 to 36 wherein the at least one SALD head further comprises a plurality of chambers for receiving a plurality of respective inserts, including the removable insert.

38. The apparatus of claim 29 wherein the at least one SALD head further comprises a gas output slit disposed in the output face, wherein the gas output slit has a non-rectangular shape to promote even flow of gas with respect to a width of the SALD head.
